(19) United States
(12) Patent Application Publication
(10) Pub. No.: US 2021/0335850 A1
(43) Pub. Date: Oct. 28, 2021

(54) DISPLAY PANEL AND MANUFACTURING METHOD THEREOF, AND ELECTRONIC EQUIPMENT

(71) Applicant: SHENZHEN CHINA STAR OPTOELECTRONICS SEMICONDUCTOR DISPLAY TECHNOLOGY CO., LTD., Shenzhen (CN)

(72) Inventor: Xingyu ZHOU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/627,778

(22) PCT Filed: Dec. 11, 2019
(86) PCT No.: PCT/CN2019/124434

§ 371 Date: Dec. 31, 2019

(30) Foreign Application Priority Data
Nov. 27, 2019 (CN) 20191183116.2

(51) Int. Cl. H01L 27/12

(52) U.S. Cl. CPC H01L 27/1251; H01L 27/127; H01L 27/1225

(57) ABSTRACT

A display panel and a manufacturing method thereof, and an electronic equipment are provided. The display panel includes a first thin film transistor and a second thin film transistor. A sectional structure of the second thin film transistor includes a second gate electrode, a second source electrode, a second drain electrode, and a second semiconductor layer. The second semiconductor layer is located on the second source electrode and the second drain electrode. Two ends of the second semiconductor layer are electrically connected to the second source electrode and the second drain electrode, respectively.

### FIELD OF INVENTION

The present disclosure relates to the field of display technology, and particularly relates to a display panel and a manufacturing method thereof, and an electronic equipment.

### BACKGROUND OF INVENTION

Two technologies of low temperature polycrystalline silicon (LTPS) and metal oxide are integrated into a low temperature polycrystalline silicon oxide (LTPO) technology, that is, simultaneously forming a first thin film transistor and a second thin film transistor in a same display panel.

However, second thin film transistors of current display panels are easy to be corroded by a metal etching solution in a manufacturing process, so performance of the thin film transistors are lowered, and then display effect is lowered.

Therefore, it is necessary to provide a display panel and a manufacturing method thereof, and an electronic equipment to solve the problem existing in the prior art.

### SUMMARY OF INVENTION

One purpose of the present disclosure is to provide a display panel and a manufacturing method thereof, and an electronic equipment, which can prevent a second semiconductor layer from being corroding by an etching solution and improves performance and display effect of a thin film transistor.

In order to solve the technical problem mentioned above, the present disclosure provides a display panel, which includes:

A first thin film transistor, a sectional structure of the first thin film transistor includes a first gate electrode, a first source electrode, a first drain electrode, and a first semiconductor layer, and two ends of the first semiconductor layer are electrically connected to the first source electrode and the first drain electrode, respectively.

A second thin film transistor, a sectional structure of the second thin film transistor includes a second gate electrode, a second source electrode, a second drain electrode, and a second semiconductor layer. The second semiconductor layer is located on the second source electrode and the second drain electrode, and two ends of the second semiconductor layer are electrically connected to the second source electrode and the second drain electrode, respectively.

The present disclosure further provides a manufacturing method of a display panel, which includes:

Manufacturing a first semiconductor layer on a base substrate.

Respectively manufacturing a first gate electrode and a second gate electrode on the first semiconductor layer.

Manufacturing a second insulation layer on the first gate electrode and the second gate electrode, wherein a plurality of first contact holes are disposed on the second insulation layer.

Respectively manufacturing a first source electrode, a first drain electrode, a second source electrode, and a second drain electrode on the second insulation layer.

Manufacturing a second semiconductor layer on the second source electrode and the second drain electrode.

The present disclosure further provides an electronic equipment, which includes the display panel mentioned above.

The display panel and the manufacturing method thereof, and the electronic equipment of the present disclosure include: the first thin film transistor, wherein the sectional structure of the first thin film transistor includes the first gate electrode, the first source electrode, the first drain electrode, and the first semiconductor layer, and two ends of the first semiconductor layer are electrically connected to the first source electrode and the first drain electrode, respectively; and the second thin film transistor, wherein the sectional structure of the second thin film transistor includes the second gate electrode, the second source electrode, the second drain electrode, and the second semiconductor layer, and the second semiconductor layer is located on the second source electrode and the second drain electrode, and two ends of the second semiconductor layer are electrically connected to the second source electrode and the second drain electrode, respectively. Furthermore, the second semiconductor layer is manufactured on the second source electrode and the second drain electrode. Therefore, this can prevent the etching solution from corroding the second semiconductor layer during the etching process of the second metal layer, and the performance and the display effect of the thin film transistors are improved.

### DESCRIPTION OF DRAWINGS

FIG. 1 is a schematic diagram of a first type structure of a current display panel.

FIG. 2 is a schematic diagram of a second type structure of a current display panel.

FIG. 3 is a structural schematic diagram of a display panel of the present disclosure.

FIG. 4 is a preferred structural schematic diagram of the display panel of the present disclosure.

FIG. 5 is a structural schematic diagram of a first substep of a first step of a manufacturing method of the display panel of the present disclosure.

FIG. 6 is a structural schematic diagram of a second substep of the first step of the manufacturing method of the display panel of the present disclosure.

FIG. 7 is a structural schematic diagram of a first substep of a second step of the manufacturing method of the display panel of the present disclosure.

FIG. 8 is a structural schematic diagram of a second substep of the second step of the manufacturing method of the display panel of the present disclosure.

FIG. 9 is a structural schematic diagram of a third step and a fourth step of the manufacturing method of the display panel of the present disclosure.

FIG. 10 is a structural schematic diagram of a fifth step of the manufacturing method of the display panel of the present disclosure.

### DETAILED DESCRIPTION OF PREFERRED EMBODIMENTS

The descriptions of embodiments below refer to accompanying drawings in order to illustrate certain embodiments which the present disclosure can implement. The directional terms of which the present disclosure mentions, for example, “top”, “bottom”, “front”, “rear”, “left”, “right”, “inside”, “side”, etc., only refer to directions of the accompanying figures. Therefore, the used directional terms are for illustrating and understanding the present disclosure, but not for limiting the present disclosure. In the figures, units with similar structures are indicated by the same reference numerals.

The terms “first”, “second”, etc. in the specification, claims, and the accompanying drawings mentioned above of the present disclosure are used to distinguish similar objects, and are not used to describe a particular order. Moreover, the terms “comprising” and “having” and any deformation of them are intended to cover non-exclusive inclusions.

As illustrated in FIG. 1, a current display panel includes a base substrate 11, and a buffer layer 12, a first semiconductor layer 13, a first insulation layer 14, a first metal layer 15, a second insulation layer 16, a second semiconductor layer 17, a second metal layer 18, a passivation layer 19, a planarization layer 20, and a pixel electrode 21 which are disposed on the base substrate 11 sequentially. The first metal layer 15 includes a first gate electrode 151 and a second gate electrode 152. The second metal layer 18 includes a first source electrode 181, a first drain electrode 182, a second source electrode 183, and a second drain electrode 184. Furthermore, the first semiconductor layer 13, the first gate electrode 151, the first source electrode 181, and the first drain electrode 182 constitute a low-temperature polycrystalline-silicon thin film transistor. The second gate electrode 152, the second semiconductor layer 17, the second source electrode 183, and the second drain electrode 184 constitute a metal oxide thin film transistor.

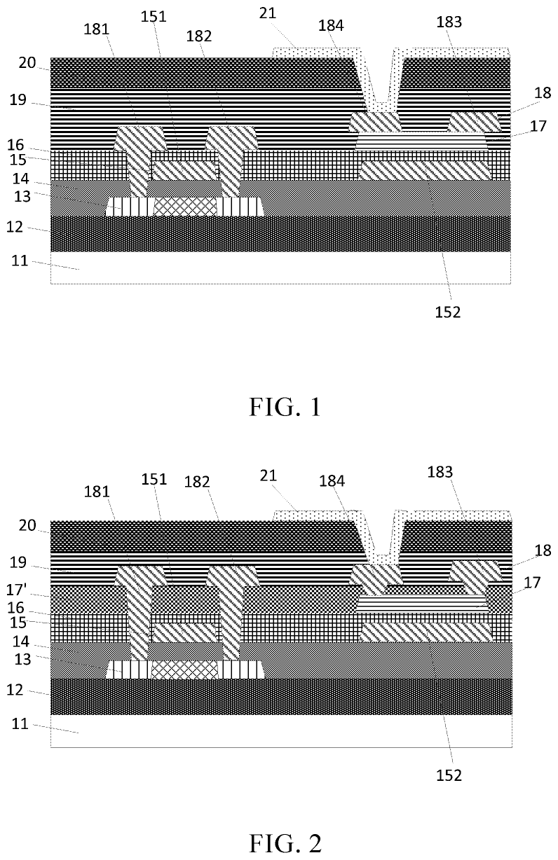

As illustrated in FIG. 2, a current display panel includes a base substrate 11, and a buffer layer 12, a first semiconductor layer 13, a first insulation layer 14, a first metal layer 15, a second insulation layer 16, a second semiconductor layer 17, an etch blocking layer 17′, a second metal layer 18, a passivation layer 19, a planarization layer 20, and a pixel electrode 21 which are disposed on the base substrate 11 sequentially.

The first metal layer 15 includes a first gate electrode 151 and a second gate electrode 152. The second metal layer 18 includes a first source electrode 181, a first drain electrode 182, a second source electrode 183, and a second drain electrode 184.

Furthermore, the first semiconductor layer 13, the first gate electrode 151, the first source electrode 181, and the first drain electrode 182 constitute a low-temperature polycrystalline-silicon thin film transistor. The second gate electrode 152, the second semiconductor layer 17, the second source electrode 183, and the second drain electrode 184 constitute a metal oxide thin film transistor.

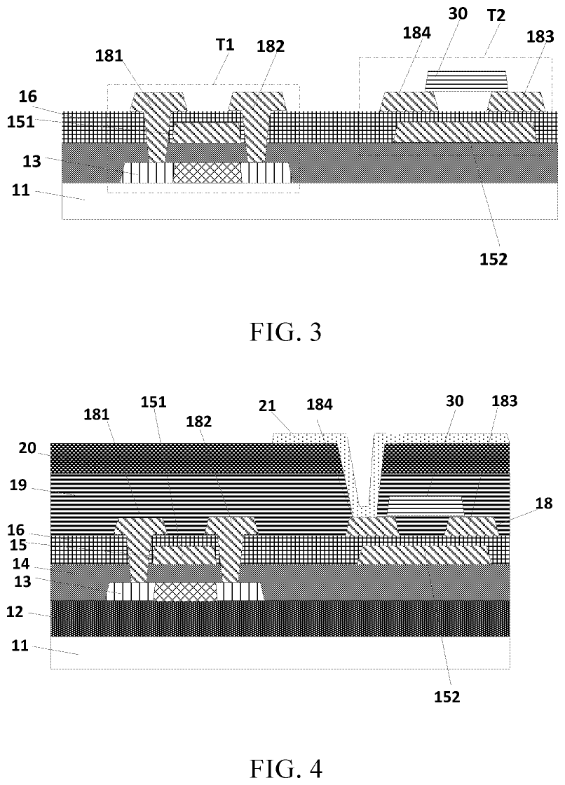

Please refer to FIG. 3, FIG. 3 is a structural schematic diagram of a display panel of the present disclosure.

The display panel of this embodiment includes a first thin film transistor T1 and a second thin film transistor T2. A sectional structure of the first thin film transistor T1 includes a first gate electrode 151, a first source electrode 181, a first drain electrode 182, and a first semiconductor layer 13. Two ends of the first semiconductor layer 13 are electrically connected to the first source electrode 181 and the first drain electrode 182, respectively, that is, one end of the first semiconductor layer 13 is electrically connected to the first source electrode 181, and another end of the first semiconductor layer 13 is electrically connected to the first drain electrode 182.

A sectional structure of the second thin film transistor T2 includes a second gate electrode 152, a second source electrode 183, a second drain electrode 184, and a second semiconductor layer 30. The second semiconductor layer 30 is located on the second source electrode 183 and the second drain electrode 184, and two ends of the second semiconductor layer 30 are electrically connected to the second source electrode 183 and the second drain electrode 184, respectively. That is, one end of the second semiconductor layer 30 is electrically connected to the second source electrode 183, and another end of the second semiconductor layer 30 is electrically connected to the second drain electrode 184. Furthermore, the second semiconductor layer 30 is used to form a second channel.

Comparing this to the structure illustrated in FIG. 1, the second semiconductor layer of this embodiment is manufactured on the second source electrode and the second drain electrode. Therefore, this can prevent an etching solution from damaging the second semiconductor layer during an etching process of the second metal layer, and the performance and the display effect of the thin film transistors are improved. Furthermore, comparing this to the structure illustrated in FIG. 2, the etch blocking layer is omitted, so that a thickness of the display panel is reduced.

Please refer to FIG. 4, which is a preferred structural schematic diagram of the display panel of the present disclosure.

The display panel of this embodiment includes a base substrate 11, and a buffer layer 12, a first semiconductor layer 13, a first insulation layer 14, a first metal layer 15, a second insulation layer 16, a second metal layer 18, and a second semiconductor layer 30 which are disposed on the base substrate 11 sequentially. In addition, the display panel may further include a third insulation layer and a pixel electrode 21. In an embodiment, the third insulation layer includes a passivation layer 19, a planarization layer 20, and a pixel electrode 21.

In an embodiment, the base substrate 11 may be a glass substrate.

The second metal layer 18 includes a first source electrode 181, first drain electrode 182, a second source electrode 183, and a second drain electrode 184. Furthermore, the first semiconductor layer 13, the first gate electrode 151, the first source electrode 181, and the first drain electrode 182 constitute a first thin film transistor, and the first thin film transistor may be a low-temperature polycrystalline-silicon thin film transistor.

The second gate electrode 152, the second source electrode 183, the second drain electrode 183, and the second semiconductor layer 30 constitute a second thin film transistor, and the second thin film transistor is a metal oxide thin film transistor.

The first metal layer 15 includes a first gate electrode 151 and a second gate electrode 152. That is, the first gate electrode 151 and the second gate electrode 152 are located on a same metal layer, so production processes are simplified. It can be understood that in other embodiment, the first gate electrode 151 and the second gate electrode 152 may be located on different metal layers.

A second insulation layer 16 is disposed between the first metal layer 15 and the second metal layer 18. A plurality of first contact holes are disposed on the second insulation layer 16 (not indicated with a reference number in the figure). The first source electrode 181 and the first drain electrode 182 are electrically connected to the first semiconductor layer 13 by one of the plurality of first contact holes, respectively.

The second metal layer 18 includes the first source electrode 181, the first drain electrode 182, the second source electrode 183, and the second drain electrode 184, that is, the first source electrode 181, the first drain electrode 182, the second source electrode 183, and the second drain electrode 184 are located on the same metal layer, so the production process can be simplified. In other embodiment, the first source electrode 181, the first drain electrode 182, the second source electrode 183, and the second drain electrode 184 may be located on different metal layers.

The two ends of the second semiconductor layer 30 are respectively in contact with the second source electrode 183 and the second drain electrode 184. That is, the second semiconductor layer 30 directly contacts with the second source electrode 183 and the second drain electrode 184, so this can omit the manufacturing of contact holes between the second semiconductor layer and the second source/drain electrode, and the production process is simplified. Of course, in other embodiment, an insulation layer may be disposed between the second semiconductor layer 30 and the second source/drain electrode. In an embodiment, in order to improve conductivity performance of the thin film transistor, a material of the first semiconductor layer 13 is polycrystalline silicon, and a material of the second semiconductor layer 30 is metal oxide. In order to improve conductivity performance of the second thin film transistor, the material of the second semiconductor layer 30 may include at least one of indium gallium zinc oxide (IGZO) or indium gallium zinc oxide (ITZO).

The passivation layer 19 and the planarization layer 20 are located on the second semiconductor layer 30. A second contact hole (not indicated with a reference number in the figure) is disposed on the passivation layer 19 and the planarization layer 20. The second drain electrode 184 is connected to the pixel electrode 21 by the second contact hole. In can be understood that the third insulation layer may be a single-layer structure.

The present disclosure further provides a manufacturing method of the display panel, including:

S101, manufacturing a first semiconductor layer on a base substrate.

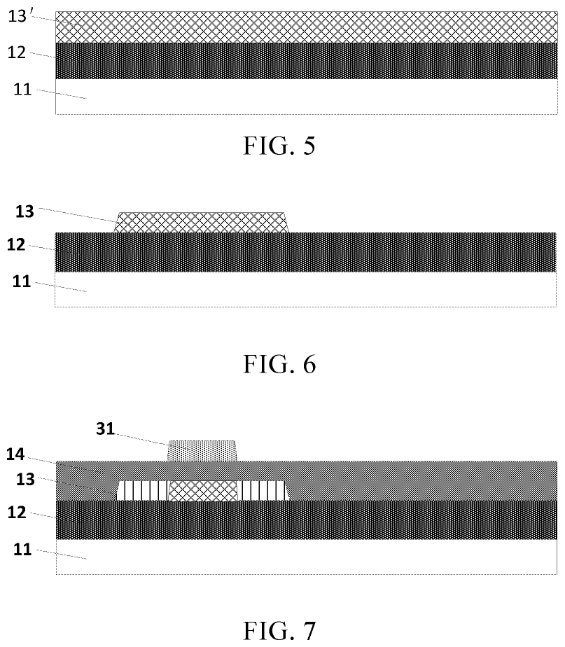

In an embodiment, the base substrate 11 is a glass substrate as an example. As illustrated in FIG. 5, for example, after cleaning and pre-baking the glass substrate, depositing buffer material on the glass substrate to form a buffer layer 12. A material of the buffer layer 12 may include at least one of SiNx or SiO₂. Afterwards, depositing amorphous silicon (a-Si) on the buffer layer 12, then performing a rapid thermal annealing process or a laser crystallization process on the a-Si to make the a-Si transform into polycrystalline silicon (poly-Si), so that a polycrystalline silicon layer 13′ is obtained. As illustrated in FIG. 6, afterwards using a photo process and an etching process to process the polycrystalline silicon layer, and defining a pattern of the semiconductor layer to obtain a patterned first semiconductor layer 13. It can be understood that the material of the first semiconductor layer 13 is not limited to polycrystalline silicon.

S102, respectively manufacturing a first gate electrode and a second gate electrode on the first semiconductor layer.

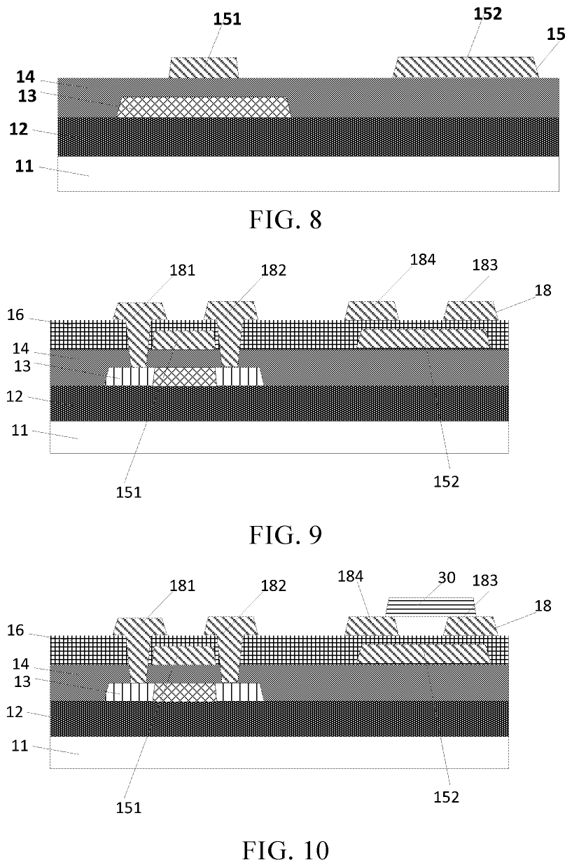

Illustrated in FIG. 7 is manufacturing a first insulation layer 14 on the first semiconductor layer 13. The first insulation layer 14 is with a single-layer film or a multi-layer film. A material of the first insulation layer 14 may include at least one of SiNx or SiO₂. Manufacturing a photoresist layer 31 on the first insulation layer 14, performing a patterning process on the photoresist layer 31, using the patterned photoresist layer 31 to act as a blocking body, and implanting ions in the first semiconductor layer 13 on two sides of the photoresist layer 31, that is, specifically, performing a doping process on the polycrystalline silicon of a source/drain region to form a heavy doping region with N+ ions or P+ ions, so that a channel is formed. After that, peeling off the photoresist layer 31. As illustrated in FIG. 8, then, depositing a first metal layer 15 on the first insulation layer 14, and performing a patterning process on the first metal layer 15 to obtain the first gate electrode 151 and the second gate electrode 152. A material of the first metal layer 15 may include at least one of Mo, Al, or Cu.

S103, manufacturing a second insulation layer on the first gate electrode and the second gate electrode. Furthermore, a plurality of second contact holes are disposed on the second insulation layer.

Illustrated in FIG. 9 is manufacturing the second insulation layer 16 on the first gate electrode 151 and the second gate electrode 152, and there are two second contact holes (not indicated with a reference number in the figure) manufactured on the second insulation layer 16. It can be understood that a number of the second contact holes may be more than two.

S104, manufacturing a first source electrode, a first drain electrode, a second source electrode, and a second drain electrode on the second insulation layer.

Illustrated in FIG. 9 is depositing a second metal layer 18 on the second insulation layer 16, and performing a patterning process on the second metal layer 18 to obtain the first source electrode 181, the first drain electrode 182, the second source electrode 183, and the second drain electrode 184. A material of the second metal layer 18 may include at least one of Mo, Al, or Cu.

S105, manufacturing a second semiconductor layer on the second source electrode and the second drain electrode.

Illustrated in FIG. 10 is depositing the second semiconductor layer 30 on the first source electrode 181, the first drain electrode 182, the second source electrode 183, and the second drain electrode 184, and performing a patterning process to obtain a required pattern. A material of the second semiconductor layer 30 may be IGZO or ITZO, etc.

The method may further include:

S106, manufacturing a third insulation layer on the second semiconductor layer. Furthermore, a second contact hole is disposed on the third insulation layer.

For example, please refer to FIG. 4, which is depositing the passivation layer 19 and the planarization layer 20 on the second semiconductor layer 30, and manufacturing the second contact hole on the passivation layer 19 and the planarization layer 20. In an embodiment, the third insulation layer may be a single-layer structure.

S107, manufacturing a pixel electrode on the third insulation layer and in the second contact hole. Furthermore, the pixel electrode is connected to the second drain electrode by the second contact hole.

For example, please refer to FIG. 4, which is manufacturing the pixel electrode 21 on the planarization layer 20 and in the second contact hole, and the pixel electrode 21 is connected to the second drain electrode 184 by the second contact hole.

Based on the previous embodiment, because the second semiconductor layer of this embodiment is directly manufactured on the second source electrode and the second drain electrode, the insulation layer therebetween can be omitted. Furthermore, the manufacturing of contact holes is prevented, so that a thickness of the display panel is reduced.

The present disclosure further provides an electronic equipment, which includes any one of the display panels mentioned above. The electronic equipment may be a mobile phone, a tablet PC, or other electronic products.

The display panel and the manufacturing method thereof, and the electronic equipment of the present disclosure, include: the first thin film transistor, wherein the sectional structure of the first thin film transistor includes the first gate electrode, the first source electrode, the first drain electrode, and the first semiconductor layer, and two ends of the first semiconductor layer are electrically connected to the first source electrode and the first drain electrode, respectively; and the second thin film transistor, wherein the sectional structure of the second thin film transistor includes the second gate electrode, the second source electrode, the second drain electrode, and the second semiconductor layer, the second semiconductor layer is located on the second source electrode and the second drain electrode, and two ends of the second semiconductor layer are electrically connected to the second source electrode and the second drain electrode, respectively. Furthermore, the second semiconductor layer is manufactured on the second source electrode and the second drain electrode. Therefore, this can prevent an etching solution from corroding the second semiconductor layer during the etching process of the second metal layer, and the performance and the display effect of the thin film transistor are improved.

In summary, although the present disclosure has disclosed the preferred embodiments as above, however the above-mentioned preferred embodiments are not to limit to the present disclosure. A person skilled in the art can make any change and modification, therefore the scope of protection of the present disclosure is subject to the scope defined by the claims.

1. A display panel comprising:
a first thin film transistor, wherein a sectional structure of the first gate electrode comprises a first source electrode, a first drain electrode, and a first semiconductor layer, and two ends of the first semiconductor layer are respectively electrically connected to the first source electrode and the first drain electrode; and
a second thin film transistor, wherein a sectional structure of the second thin film transistor comprises a second gate electrode, a second source electrode, a second drain electrode, and a second semiconductor layer, the second semiconductor layer is located on the second source electrode and the second drain electrode, and two ends of the second semiconductor layer are respectively electrically connected to the second source electrode and the second drain electrode.

2. The display panel as claimed in claim 1, wherein
the two ends of the second semiconductor layer are respectively in contact with the second source electrode and the second drain electrode.

3. The display panel as claimed in claim 1, wherein
a first insulation layer is located on the first semiconductor layer, a first metal layer is located on the first insulation layer, and a second metal layer is located on the first metal layer;
the first source electrode, the first drain electrode, the second source electrode, and the second drain electrode are located on the second metal layer.

4. The display panel as claimed in claim 3, wherein
the first gate electrode and the second gate electrode are located on the first metal layer, and the first source electrode, the first drain electrode, the second source electrode, and the second drain electrode are located on the second metal layer; and
the display panel comprises:
a second insulation layer disposed between the first metal layer and the second metal layer, and a plurality of first contact holes disposed on the second insulation layer, wherein the first source electrode and the first drain electrode are electrically connected to the first semiconductor layer by one of the plurality of first contact holes, respectively.

5. The display panel as claimed in claim 3, wherein
the first gate electrode and the second gate electrode are located on the first metal layer.

6. The display panel as claimed in claim 1, wherein
the display panel comprises:
a third insulation layer located on the second semiconductor layer, a second contact hole is disposed on the third insulation layer, and the second drain electrode is connected to a pixel electrode through the second contact hole.

7. The display panel as claimed in claim 3, wherein material of the second metal layer comprises at least one of Mo, Al, or Cu.

8. The display panel as claimed in claim 1, wherein
the first thin film transistor is a low-temperature polycrystalline-silicon thin film transistor, and the second thin film transistor is a metal oxide thin film transistor.

9. The display panel as claimed in claim 7, wherein
material of the second semiconductor layer comprises at least one of indium gallium zinc oxide (IGZO) or indium gallium zinc oxide (ITZO).

10. A manufacturing method of a display panel, comprising:
manufacturing a first semiconductor layer on a base substrate;
manufacturing a first insulation layer on the first semiconductor layer;
respectively manufacturing a first gate electrode and a second gate electrode on the first semiconductor layer;
manufacturing a second insulation layer on the first gate electrode and the second gate electrode, wherein a plurality of first contact holes are disposed on the second insulation layer;
respectively manufacturing a first source electrode, a first drain electrode, a second source electrode, and a second drain electrode on the second insulation layer; and
manufacturing a second semiconductor layer on the second source electrode and the second drain electrode.

11. The manufacturing method of the display panel as claimed in claim 10, wherein the manufacturing method comprises:
manufacturing a third insulation layer on the second semiconductor layer, wherein a second contact hole is disposed on the third insulation layer; and
manufacturing a pixel electrode on the third insulation layer and in the second contact hole, wherein the pixel electrode is connected to the second drain electrode by the second contact hole.

12. An electronic equipment, comprising a display panel, wherein the display panel comprises:
a first thin film transistor, wherein a sectional structure of the first thin film transistor comprises a first gate electrode, a first source electrode, a first drain electrode, and a first semiconductor layer, and two ends of the first semiconductor layer are electrically connected to the first source electrode and the first drain electrode, respectively; and
a second thin film transistor, wherein a sectional structure of the second thin film transistor comprises a second gate electrode, a second source electrode, a second drain electrode, and a second semiconductor layer, the second semiconductor layer is located on the second source electrode and the second drain electrode, and two ends of the second semiconductor layer are electrically connected to the second source electrode and the second drain electrode, respectively.

13. The electronic equipment as claimed in claim 12, wherein
the two ends of the second semiconductor layer are respectively in contact with the second source electrode and the second drain electrode.

14. The electronic equipment as claimed in claim 12, wherein
a first insulation layer is located on the first semiconductor layer, a first metal layer is located on the first insulation layer, and a second metal layer is located on the first metal layer;
the first source electrode, the first drain electrode, the second source electrode, and the second drain electrode are located on the second metal layer.

15. The electronic equipment as claimed in claim 14, wherein
the first gate electrode and the second gate electrode are located on the first metal layer, and the first source electrode, the first drain electrode, the second source electrode, and the second drain electrode are located on the second metal layer; and
the display panel comprises:
a second insulation layer disposed between the first metal layer and the second metal layer, and a plurality of first contact holes disposed on the second insulation layer, wherein the first source electrode and the first drain electrode are electrically connected to the first semiconductor layer by one of the plurality of first contact holes, respectively.

16. The display panel as claimed in claim 14, wherein
the first gate electrode and the second gate electrode are located on the first metal layer.

17. The electronic equipment as claimed in claim 12, wherein
the display panel comprises:
a third insulation layer located on the second semiconductor layer, a second contact hole is disposed on the third insulation layer, and the second drain electrode is connected to a pixel electrode through the second contact hole.

18. The electronic equipment as claimed in claim 14, wherein
a material of the second metal layer comprises at least one of Mo, Al, or Cu.

19. The electronic equipment as claimed in claim 12, wherein
the first thin film transistor is a low-temperature polycrystalline-silicon thin film transistor, and the second thin film transistor is a metal oxide thin film transistor.

20. The electronic equipment as claimed in claim 19, wherein material of the second semiconductor layer comprises at least one of indium gallium zinc oxide (IGZO) or indium gallium zinc oxide (ITZO).
